(19) United States
(12) Patent Application Publication
(10) Pub. No.: US 2006/0176096 A1
(43) Pub. Date: Aug. 10, 2006

(54) Power supply insensitive delay element

(75) Inventors: Daniel M. Dreps, Georgetown, TX (US); Frank D. Ferraiolo, New Windsor, NY (US); Daniel J. Friedman, Sleepy Hollow, NY (US); Seongwon Kim, Old Tappan, NJ (US); Robert J. Reese, Austin, TX (US); Hector Saenz, Round Rock, TX (US); Michael A. Sperling, Poughkeepsie, NY (US)

Correspondence Address: HESLIN ROTHENBERG FARLEY & MESITI P.C., 5 COLUMBIA CIRCLE, ALBANY, NY, 12203, US

(73) Assignee: International Business Machines Corporation, Armonk, NY (US)

(21) Appl. No.: 11/056,798

(22) Filed: Feb. 10, 2005

(51) Int. Cl. H03H 11/26

(52) U.S. Cl. 327/262

(57) ABSTRACT

A power supply voltage insensitive delay element is provided that enables a digital signal to be delayed without variation due to power supply vulnerabilities. Current is limited through the transistors of the delay element using bias voltages produced by a bias voltage generator coupled to the delay element. The bias voltage generator and the delay element are included in a delay line which facilitates the providing of a delay that is insensitive to voltage fluctuations.

### CROSS-REFERENCE TO RELATED APPLICATIONS

This application contains subject matter which is related to the subject matter of the following application, which is assigned to the same assignee as this application, and is hereby incorporated herein by reference in its entirety:

“On-Chip Detection Of Power Supply Vulnerabilities,” Ferraiolo et al., (IBM Docket No.: POU920040247US1), U.S. Ser. No. ______; filed herewith.

### TECHNICAL FIELD

This invention relates, in general, to delaying signals, and in particular, to providing a delay element, that is insensitive to power supply vulnerabilities, to delay the signals.

### BACKGROUND OF THE INVENTION

As the operation speed of computer systems continues to increase, so does the need to delay clock and/or data signals to optimize critical timing within the computer systems. Further, as the clock rate in the systems increases, the timing between the computer elements and within the computer chips becomes critical.

Currently, timing is provided through the use of delay elements controllable via digital delay locked loops. Examples of delay elements are described in the following patents, each of which is hereby incorporated herein by reference in its entirety: “Multi-tap Digital Delay Line,” Llewellyn, U.S. Pat. No. 5,374,860, issued Dec. 20, 1994; “Programmable Digital Delay Unit,” Moloney et al., U.S. Pat. No. 5,670,904, issued Sep. 23, 1997; “Variable Impedance Delay Elements,” McClure, U.S. Pat. No. 6,014,050, issued Jan. 11, 2000; “Digital Programmable Delay Element,” Voss, U.S. Pat. No. 6,255,879 B1, issued Jul. 3, 2001; “Digital Delay Line With Low Insertion Delay,” Chu et al., U.S. Pat. No. 6,285,229 B1, issued Sep. 4, 2001; “Programmable Delay Circuit Having A Fine Delay Element Selectively Receives Input Signal And Output Signal Of Coarse Delay Element,” Chu et al., U.S. Pat. No. 6,421,784 B1, issued Jul. 16, 2002; “Linear Delay Element Providing Linear Delay Steps,” Dreps et al., U.S. Pat. No. 6,546,530 B1, issued Apr. 8, 2003; “Programmable Delay Elements For Source Synchronous Link Function Design Verification Through Simulation,” Jue et al., U.S. Pat. No. 6,611,936 B2, issued Aug. 26, 2003; and “Input/Output Cell With A Programmable Delay Element,” Rotker, U.S. Pat. No. 6,708,238 B1, issued Mar. 16, 2004.

### SUMMARY OF THE INVENTION

Current delay elements are typically limited to coarse variable delays where the incremental delay unit is one or two logic gates. Further, conventional delay elements are sensitive to power supply noise and other vulnerabilities. This is a significant disadvantage since any variation in delay decreases overall performance. Thus, a need exists for a delay element that has a constant delay against voltage variation. Further, a need exists for a delay element that is insensitive to power supply vulnerabilities.

The shortcomings of the prior art are realized and overcome and additional advantages are provided through the provision of a delay circuit to delay a signal. The delay circuit includes, for instance, a delay element that is insensitive to one or more vulnerabilities of a power supply of the delay element.

In a further aspect of the present invention, a delay line is provided. The delay line includes, for instance, a reference current generator to provide a reference current; a bias voltage generator coupled to the reference current generator to receive current from the reference current generator and to provide one or more bias voltages; and a delay element coupled to the bias voltage generator to delay a signal, the delay element to receive the one or more bias voltages and to employ the one or more bias voltages to limit current through the delay element enabling the delay element to be insensitive to one or more vulnerabilities of a power supply of the delay element.

In yet another aspect of the present invention, a method of delaying a signal is provided. The method includes, for instance, providing a delay element that is insensitive to one or more vulnerabilities of a power supply of the delay element; and employing the delay element to delay the signal.

Additional features and advantages are realized through the techniques of the present invention. Other embodiments and aspects of the invention are described in detail herein and are considered a part of the claimed invention.

### BRIEF DESCRIPTION OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 depicts one example of a delay element that is sensitive to power supply vulnerabilities;

FIG. 2 depicts one example of a delay element that is insensitive to power supply vulnerabilities, in accordance with an aspect of the present invention;

FIG. 3 depicts one embodiment of a block diagram of a delay line that includes the delay element of FIG. 2, in accordance with an aspect of the present invention; and

FIG. 4 depicts further details of a bias voltage generator of the delay line of FIG. 3, in accordance with an aspect of the present invention.

### BEST MODE FOR CARRYING OUT THE INVENTION

A signal, such as a clock signal and/or a data signal, is often delayed to ensure proper timing between, for instance, computing components of one or more computing chips. In accordance with an aspect of the present invention, this delay is provided by a delay element that is insensitive to power supply vulnerabilities. That is, the delay varies proportionally less than the power supply fluctuations. In one example, the delay through the delay element remains constant (i.e., with little or no variation; e.g., +/− about 1% of variation) even when there is variation in the power supply voltage due to power supply vulnerabilities, such as noise. As one particular example, the delay element is a component of a delay line that facilitates the providing of a constant delay.

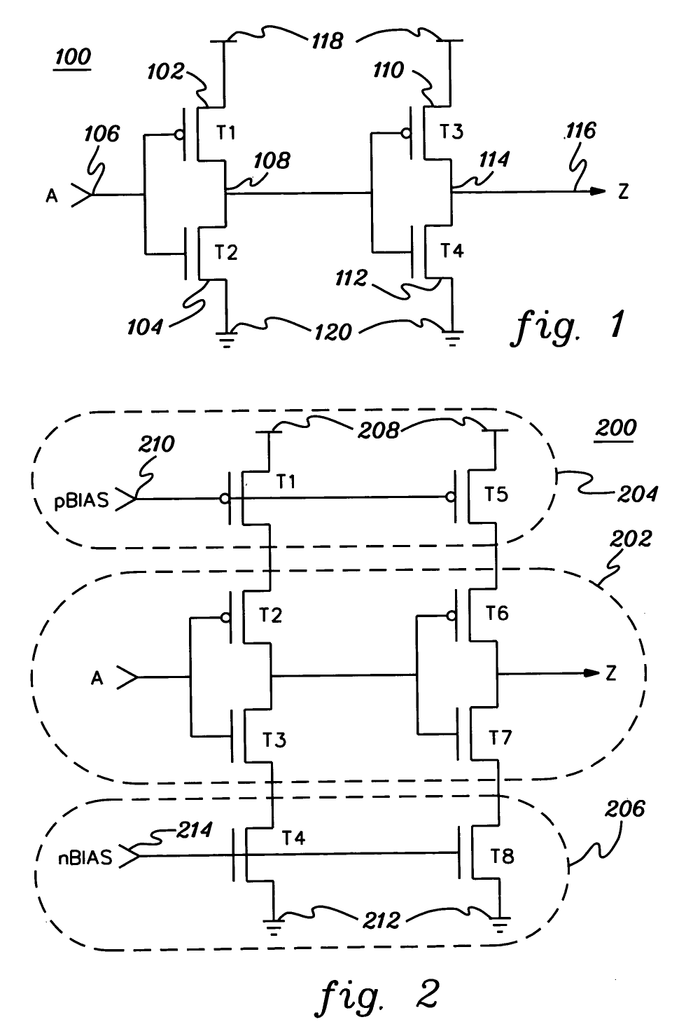

Delay elements have previously been used to provide delay, but existing delay elements are sensitive to power supply noise and other vulnerabilities. One example of a power supply sensitive delay element is described with reference to FIG. 1.

As shown in FIG. 1, a delay element 100 includes a double inverter structure in which a transistor 102 (T1) and a transistor 104 (T2) are gated by an input signal 106 (A). Transistors 102 and 104 have commonly connected drains 108, which gate a second set of transistors 110 (T3) and 112 (T4). The drains of those transistors are also commonly connected (114) and provide the output at 116 (Z).

In this example, transistors T1 and T3 are PFET transistors tied to a power supply (VDD) 118 of the delay element, and transistors T2 and T4 are NFET transistors tied to ground 120.

The delay is determined by the amount of current through the transistors and the capacitive load at their output. The load that the transistors see is constant, since it is a parasitic gate capacitance. The current through the transistors is varied by any supply voltage (VDD) variation, since it is proportional to gate-to-source voltage. This delay element is thus sensitive to vulnerabilities of the power supply of the delay element.

In accordance with an aspect of the present invention, a delay element is provided that is insensitive to vulnerabilities in the power supply. These vulnerabilities include noise and/or other external factors that cause unwanted voltage fluctuations, as examples. One embodiment of an insensitive delay element is described below with reference to FIG. 2.

A delay element 200 includes, for instance, a double inverter structure 202, similar to the inverter structure described with reference to FIG. 1, as well as a header structure 204 and a footer structure 206 coupled thereto. For instance, the sources of transistors T2 and T6 of inverter structure 202 are connected to the drains of transistors T1 and T5, respectively, of header structure 204. Similarly, the sources of transistors T3 and T7 of inverter structure 202 are connected to the drains of transistors T4 and T8, respectively, of footer structure 206.

Transistors T1 and T5 are tied to a power supply (VDD) 208, and they are gated by an input 210, referred to as pBIAS, as described below. Further, transistors T4 and T8 are tied to ground 212 and are gated by an input 214, referred to as nBIAS, which is also described below. In this example, the transistors of header structure 204 are PFET transistors and the transistors of footer structure 206 are NFET transistors. However, in other examples, the type of transistors in either structure or in the inverter structure may be different than that shown here.

Delay element 200 has a characteristic of producing constant delay within a range of voltage variation (e.g., +/−15% of variation). This is possible by limiting the current through the transistors using the pBIAS and nBIAS voltages. Since PFET transistors T1 and T5's gate-to-source voltage is held constant by the pBIAS input voltage, the current through T1 and T5 is held constant against unwanted VDD fluctuations. The same is true with NFET transistors T4 and T8 where the gate voltage is provided by the nBIAS input voltage.

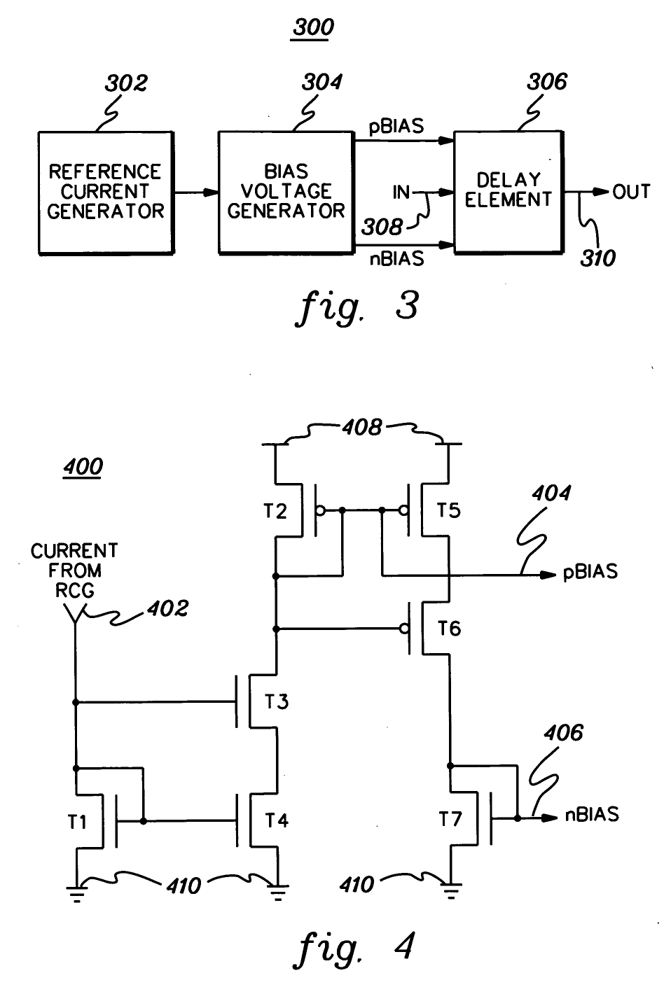

The inputs, pBIAS and nBIAS, of delay element 200 are provided by a bias voltage generator, which is coupled to the delay element, as depicted in FIG. 3. Specifically, in this embodiment, the delay element and the bias voltage generator are components of a delay line 300 used to facilitate the providing of power supply insensitive delay.

As one example, delay line 300 includes, for instance, a reference current generator 302 coupled to a bias voltage generator 304 which is further coupled to a delay element 306. Reference current generator 302 generates a constant amount of current regardless of the power supply voltage variation (i.e., regardless of unwanted variation within a range due to power supply vulnerabilities). This reference current is used by the bias voltage generator to generate reference voltages for the delay element. The delay element's delay is determined by the amount of current generated by the reference current generator, which shows constant current against voltage variation. Thus, the delay element has an enhanced power supply insensitivity compared with conventional delay elements.

Reference current generator 302 is a conventional circuit, such as a bandgap reference circuit or a resistor based circuit, which is used to provide a constant (e.g., little or no change) current reference. The bandgap based reference current generator provides a constant current against any power supply voltage and temperature variations. One example of a bandgap reference circuit is described in U.S. Pat. No. 5,053,640, entitled “Bandgap Voltage Reference Circuit,” Yum, issued Oct. 1, 1991, which is hereby incorporated herein by reference in its entirety.

The output of the reference current generator is input to bias voltage generator 304, which uses the reference current from the reference current generator to generate pBIAS and nBIAS voltages that are used to set the delay in the delay element. One function of this circuit is to form a constant voltage from VDD-to-pBIAS and nBIAS-to-ground (GND). This is accomplished by mirroring the reference current generator input current to a second branch, as described with reference to FIG. 4.

FIG. 4 depicts one example of a bias voltage generator 400. Input to bias voltage generator 400 is current from the reference current generator as indicated at 402. There are two outputs, pBIAS 404 and nBIAS 406. The current input is gated to transistors T1, T3 and T4. Mirroring is provided from T1 to T4 and a cascode is added by the provision of transistor T3. Transistor T3 is coupled in series with transistors T2 and T4. Further, a mirror is provided from transistor T2 to T5, which are tied to a power supply 408. A cascode is added by the inclusion of transistor T6. Transistors T2, T5 and T6 are gated to the same source. Transistors T5 and T6 are coupled in series with transistor T7. The gate voltages of T6 and T7 provide a pBIAS output voltage 404 and NBIAS output voltage 406, respectively. Transistors, T1, T4 and T7 are tied to ground 410.

In this particular embodiment, transistors T3 and T6 have a low voltage threshold (VT), i.e., a voltage threshold lower than that of T4 and T5, respectively (e.g., approximately, 30% lower). By using low VT transistors, cascoding is provided without the need for additional bias voltage, since the gate voltage of T3 and T4 is shared. By cascoding these two lines, there is higher impedance looking at the output of the two current mirrors. This higher impedance gives better current matching in a current mirror.

Referring back to FIG. 3, the outputs of the bias voltage generator, pBIAS and nBIAS, are input to delay element 306. One example of delay element 306 is described with reference to FIG. 2. The pBIAS and nBIAS voltages are used to provide a delay that is insensitive to power supply voltage vulnerabilities. A signal, such as a clock, data or other digital signal, is input at 308 and a delayed signal is output at 310. The delay provided through the delay element is relatively insensitive to power supply noise and other vulnerabilities (e.g., the delay does not change within +/−15% of voltage variation).

Described in detail above is a capability of providing a delay that is insensitive to voltage fluctuation (i.e., noise, voltage sensitivity, etc.). That is, typically the delay changes proportional to voltage fluctuation, e.g., a 10% change in voltage yields a 10% change in delay. However, in accordance with an aspect of the present invention, the delay is insensitive to voltage fluctuation in that a change in voltage fluctuation causes a less than proportional change in delay (e.g., a 10% change in voltage fluctuation yields less than a 10% change in delay). As one example, the delay is provided by a delay element capable of producing constant delay regardless of power supply variation. That is, there is little or no variation in the delay (e.g., approximately +/−1% of variation). In other embodiments, however, the change in delay is greater, but still less than proportional to the change in voltage fluctuation. As examples, the change in delay may be +/−2%, 3% or other percents. These are all considered within the spirit of one or more aspects of the present invention. The delay element is included within a delay line, in one example, which provides the voltage to the delay element.

The delay line includes, for instance, an analog reference generator, which produces a constant current to be used as a reference for the delay element. The delay element uses the reference current to produce a constant unit delay. The constant unit delay is an important consideration particularly when deskewing data, since any variation in delay decreases overall performance. The unit delay is insensitive to power supply noise or other power supply sensitivities or vulnerabilities. The delay line has an analog reference generator with an impedance controlled delay element to increase power supply voltage insensitivity. The delay element having a constant delay against voltage variation is provided for use in, for instance, high performance computer systems, such as the PowerPC offered by International Business Machines Corporation, Armonk, N.Y. or other microprocessors, as examples.

Although examples are provided above, these are only examples. Many variations may be made without departing from the spirit of one or more aspects of the present invention. For instance, different types of transistors may be used in one or more of the structures or circuits, more or less transistors may be used in one or more of the structures or circuits, etc. Moreover, structures or logic circuits other than inverter structures may be used as or in the delay elements. Many other variations are also possible.

The diagrams depicted herein are just examples. There may be many variations to these diagrams without departing from the spirit of the invention. For instance, other types of transistors may be used. Additionally, more or less transistors may be used. All of these variations are considered a part of the claimed invention.

Although preferred embodiments have been depicted and described in detail herein, it will be apparent to those skilled in the relevant art that various modifications, additions, substitutions and the like can be made without departing from the spirit of the invention and these are therefore considered to be within the scope of the invention as defined in the following claims.

What is claimed is:

1. A delay circuit to delay a signal, said delay circuit comprising:
a delay element that is insensitive to one or more vulnerabilities of a power supply of the delay element.

2. The delay circuit of claim 1, wherein the delay element receives as input one or more bias voltages, said one or more bias voltages to provide a constant voltage within the delay element.

3. The delay circuit of claim 1, further comprising a bias voltage generator coupled to the delay element to provide one or more bias voltages to the delay element.

4. The delay circuit of claim 3, wherein the one or more bias voltages comprise a pBIAS voltage and an NBIAS voltage.

5. The delay circuit of claim 3, wherein the bias voltage generator generates the one or more bias voltages from current received as an input to the bias voltage generator.

6. The delay circuit of claim 5, wherein the current is provided by a reference current generator coupled to the bias voltage generator.

7. The delay circuit of claim 3, wherein the one or more bias voltages are used to limit current through the delay element enabling the delay element to be insensitive to power supply voltage vulnerabilities.

8. The delay circuit of claim 3, wherein the bias voltage generator includes at least one cascoded current mirror, wherein a transistor of a cascoded current mirror of the at least one cascoded current mirror comprises a low voltage threshold transistor.

9. The delay circuit of claim 8, wherein the low voltage threshold transistor shares a gate voltage with one or more other transistors of the cascoded current mirror.

10. The delay circuit of claim 1, wherein the delay element comprises at least one inverter structure.

11. The delay circuit of claim 10, wherein an inverter structure of the at least one inverter structure comprises a first transistor for limiting current from a power supply of the delay element, a second transistor for switching due to an input signal of the delay element, a third transistor for switching due to the input signal, and a fourth transistor for limiting current to ground.

12. The delay circuit of claim 11, wherein the first transistor and the second transistor comprise PFET transistors, and the third transistor and the fourth transistor comprise NFET transistors.

13. The delay circuit of claim 12, wherein a gate voltage of the first transistor comprises a pBIAS voltage input to the delay element and a gate voltage of the fourth transistor comprises an nBIAS voltage input to the delay element.

14. The delay circuit of claim 1, wherein the one or more vulnerabilities comprise noise.

15. A delay line comprising:
a reference current generator to provide a reference current;
a bias voltage generator coupled to the reference current generator to receive current from the reference current generator and to provide one or more bias voltages; and
a delay element coupled to the bias voltage generator to delay a signal, said delay element to receive the one or more bias voltages and to employ the one or more bias voltages to limit current through the delay element to enable the delay element to be insensitive to one or more vulnerabilities of a power supply of the delay element.

16. A method of delaying a signal, said method comprising:
providing a delay element that is insensitive to one or more vulnerabilities of a power supply of the delay element; and
employing the delay element to delay the signal.

17. The method of claim 16, wherein the delay element receives as input one or more bias voltages used to limit current through the delay element enabling the delay element to be insensitive to the one or more vulnerabilities.

18. The method of claim 17, further comprising generating the one or more bias voltages.

19. The method of claim 18, wherein the generating comprises using a reference current to generate the one or more bias voltages.

20. The method of claim 19, wherein the reference current is provided by a reference current generator and the generating is performed by a bias voltage generator coupled to the reference current generator and to the delay element.

21. The method of claim 20, wherein the reference current generator, the bias voltage generator and the delay element comprise a delay line.

22. The method of claim 20, wherein the bias voltage generator comprises at least one cascoded current mirror, wherein a transistor of a cascoded current mirror of the at least one cascoded current mirror comprises a low voltage threshold transistor.

23. The method of claim 22, wherein the low voltage threshold transistor shares a gate voltage with one or more other transistors of the cascoded current mirror.

24. The method of claim 16, wherein the delay element comprises at least one inverter structure.

25. The method of claim 24, wherein an inverter structure of the at least one inverter structure comprises a first transistor for limiting current from a power supply of the delay element, a second transistor for switching due to an input signal of the delay element, a third transistor for switching due to the input signal, and a fourth transistor for limiting current to ground.

26. The method of claim 25, wherein the first transistor and the second transistor comprise PFET transistors, and the third transistor and fourth transistor comprise NFET transistors.

27. The method of claim 26, wherein a gate voltage of the first transistor comprises a pBIAS voltage input to the delay element and a gate voltage of the fourth transistor comprises an nBIAS voltage input to the delay element.
